(19) United States
(12) Patent Application Publication
(10) Pub. No.: US 2026/0122965 A1
(43) Pub. Date: Apr. 30, 2026

(54) POWER SEMICONDUCTOR DEVICE

(71) Applicant: invinci semiconductor corporation, Taipei (TW)

(72) Inventors: Hsu-Heng Lee, Taipei (TW); Mei-Ling Chen, Taipei (TW); Li-Ming Chang, Taipei (TW)

(21) Appl. No.: 19/432,148

(22) Filed: Dec. 24, 2025

Related U.S. Application Data
(63) Continuation of application No. 17/527,180, filed on Nov. 16, 2021.

(30) Foreign Application Priority Data
Nov. 16, 2020 (CN) 202011278464.0

(51) Int. Cl. H10D 30/66; H10D 30/01; H10D 62/10; H10D 84/00

(52) U.S. Cl. CPC H10D 30/668; H10D 30/0297; H10D 62/111; H10D 84/143

(57) ABSTRACT

A power semiconductor device including an epitaxial layer and a fabrication method thereof. A first well region and a second well region separated from each other respectively extend from a surface of the epitaxial layer into the epitaxial layer. A floating doped region is located in the epitaxial layer and between the first well region and the second well region. The floating doped region is separated from the first well region and the second well region. A first doped region and a second doped region respectively extend from the surface of the epitaxial layer into the first well region and the second well region. A gate structure is located on the epitaxial layer and is adjacent to the first doped region and the second doped region. The gate structure is at least partially overlapped with the floating doped region.

### CROSS-REFERENCE TO RELATED PATENT APPLICATION

This application is a Continuation Application of the U.S. application Ser. No. 17/527,180, filed on Nov. 16 2021 and entitled “POWER SEMICONDUCTOR DEVICE AND FABRICATION METHOD THEREOF”, now pending, the entire disclosures of which are incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The disclosure relates to a power electronic device and a fabrication method thereof, and in particular, to a power semiconductor device and a fabrication method thereof.

### BACKGROUND OF THE DISCLOSURE

The disclosure relates to a power electronic device and a fabrication method thereof, and in particular, to a power semiconductor device and a fabrication method thereof.

In our daily lives, all the household appliances and mechanical equipment used in various industries are equipped with a power system supplying the power for operation. During the process of power transmission and consumption, a power electronic device is required for power conversion to control the current stability in the power system when a sudden increase in voltage occurs.

A power semiconductor device exhibits the higher input impedance, lower driving power, lower on-resistance value, faster switch speed, less switch consumption, and broader safe of operation area (SOA) and is suitable for being integrated with an integrated circuit fabricating process to form a power integrated circuit. Therefore, the power semiconductor device is frequently applied to the power conversion system of consumer electronics (e.g. portable electronic products such as MP3 players, digital cameras, laptops, smart phones, and the like).

The structures of power semiconductor devices, such as power metal-oxide-semiconductor transistors, may be classified into planar structures and vertical structures according to current flowing paths. Since the planar structure requires a wider channel to accommodate more currents to reduce the on-resistance when it is operated in an environment with a high voltage and a high current, it occupies a relatively larger area of the integrated circuit. As for the vertical structure, since the channel width is the thickness of an epitaxial layer, the on-current of a unit IC area unit may be increased by increasing the thickness of the epitaxial layer. With micro-miniaturization of integrated circuits, the vertical structure has become the mainstream in power metal-oxide-semiconductor transistor devices.

A typical vertically-structured power metal-oxide-semiconductor transistor device (e.g. an n-type channel vertical double-diffused power metal-oxide-semiconductor transistor device) includes a substrate (a drain), an n-type epitaxial layer located above the substrate, two p-type well regions located in the n-type epitaxial layer and separated from each other, two n-type source doped regions respectively extending downwards from the upper surface of the n-type epitaxial layer into the two p-type well regions, and a gate structure located on the n-type epitaxial layer and adjacent to the n-type source doped regions.

A parasitic junction gate field-effect transistor (JFET) is present between the drain and the source of the vertical-structured power metal-oxide-semiconductor transistor device. Therefore, when a positive voltage is applied to the drain in a forward operation, a forward bias voltage causes majority holes to pass through the P-N junction between the p-type well regions and the n-type epitaxial layer and be injected into the n-type epitaxial layer. When a reverse bias voltage is applied to the drain during a reverse operation, since electrons are not injected from the source, minority carriers (holes) accumulated on the P-N junction need to be recombined with opposite charges (electrons) before the device is turned off. As a result, the current does not drop to zero instantly. Instead, it takes a period of reverse recovery time before power conversion is performed, which leads to a limitation on the vertical-structured power metal-oxide-semiconductor transistor device in the environment of high-frequency operation.

Therefore, a power semiconductor device and a fabrication method thereof are still required.

### SUMMARY OF THE DISCLOSURE

An embodiment of the disclosure is directed to a power semiconductor device. The power semiconductor device includes an epitaxial layer having a first conductive type, a first well region, a second well region, a floating doped region, a first doped region, a second doped region, and a gate structure. The first well region and the second well region have a second conductive type and respectively extend from a surface of the epitaxial layer into the epitaxial layer. The first well region and the second well region are separated from each other. The floating doped region has the second conductive type and is located in the epitaxial layer and between the first well region and the second well region. The floating doped region is separated from the first well region and the second well region. The first doped region and the second doped region have the first conductive type and respectively extend from the surface of the epitaxial layer into the first well region and the second well region. The gate structure is located on the epitaxial layer and is adjacent to the first doped region and the second doped region. The gate structure is at least partially overlapped with the floating doped region.

Another embodiment of the disclosure provides a power semiconductor device. The power semiconductor device includes an epitaxial layer having the first conductive type, the first well region, the second well region, the floating doped region, and a metal electrode. The first well region and the second well region have the second conductive type and respectively extend from the surface of the epitaxial layer into the epitaxial layer. The first well region and the second well region are separated from each other. The floating doped region has the second conductive type and is located in the epitaxial layer and between the first well region and the second well region. The floating doped region is separated from the first well region and the second well region. The metal electrode is located on the epitaxial layer and forms a metal-semiconductor junction respectively with the first well region and the second well region.

Still another embodiment of the disclosure provides a fabrication method of a power semiconductor device. The fabrication method of the power semiconductor device includes the following. First, an epitaxial layer having a first conductive type is provided. A floating doped region having a second property is formed in the epitaxial layer. Next, a gate structure is formed on the epitaxial layer and is at least partially overlapped with the floating doped region. A first well region and a second well region that are separated from each other and have the second conductive type are formed in the epitaxial layer. The first well region and the second well region extend from a surface of the epitaxial layer into the epitaxial layer so that the floating doped region is located between the first well region and the second well region and is separated from the first well region and the second well region. The first doped region and the second doped region having the first conductive type are formed and respectively extend from the surface of the epitaxial layer into the first well region and the second well region. The first doped region and the second doped region are adjacent to the gate structure.

According to the embodiments above, in the power semiconductor device and the fabrication method thereof according to the disclosure, at least one transistor unit or metal-semiconductor junction diode unit having a vertical channel and an NPN parasitic bipolar junction is formed in the epitaxial layer having the first conductive type. Furthermore, the floating doped region having the second conductive type is disposed in the epitaxial layer to change a vertical electrical field distribution in the transistor/diode unit. When the transistor unit/diode is operated reversely, the injection of electrons from the drain into a parasitic PN junction between the drain and the source is facilitated so that the electrons are recombined with minority carriers accumulated on the PN junction. The reverse recovery time required to turn off a field effect transistor unit can be reduced without changing the rated operation voltage, which is favorable for the power semiconductor device to be operated at a high frequency.

### BRIEF DESCRIPTION OF THE DRAWINGS

In order to make the aforementioned features and advantages of the disclosure comprehensible, embodiments are described in detail below. Note that the specific embodiments and implementations are not intended to limit the disclosure. The disclosure may be implemented by adopting other features, elements, methods, and parameters. The embodiments are used to illustrate the technological features of the disclosure, and they are not intended to limit the disclosure.

FIG. 1A to FIG. 1F are schematic cross-sectional views of structures in a series of fabrication processes of fabricating a power semiconductor device according to an embodiment of the disclosure.

FIG. 2 is a schematic cross-sectional view of a structure of a power semiconductor device according to another embodiment of the disclosure.

FIG. 3A to FIG. 3F are schematic cross-sectional views respectively illustrating structures of power semiconductor devices having floating doped regions with different structures according to some embodiments of the disclosure.

FIG. 4A to FIG. 4D are schematic cross-sectional views of structures of some of the fabrication processes of fabricating a power semiconductor device according to still another embodiment of the disclosure.

FIG. 5A to FIG. 5E are schematic cross-sectional views of structures of some of the fabrication processes of fabricating a power semiconductor device according to yet another embodiment of the disclosure.

FIG. 6 is a schematic cross-sectional view of a structure of a power semiconductor device according to yet another embodiment of the disclosure.

FIG. 7A to FIG. 7D are schematic cross-sectional views of structures of a power semiconductor device according to yet another embodiment of the disclosure.

FIG. 8 is a schematic cross-sectional view of a structure of a power semiconductor device according to yet another embodiment of the disclosure.

FIG. 9 is a curve chart of a relation between a reverse recovery current and a reverse recovery time obtained when the power semiconductor device provided in FIG. 4D and a conventional super junction metal oxide-semiconductor transistor unit underwent a reverse recovery test.

### DETAILED DESCRIPTION OF THE EXEMPLARY EMBODIMENTS

The disclosure provides a power semiconductor device and a fabrication method thereof capable of effectively reducing a reverse current and power consumption when a device switch operations, without changing a rated operation voltage, and increasing a critical voltage of the device when the device is switched to be turned off. Several embodiments are described below with reference to the drawings. In the drawings, the same or similar reference numerals are used to refer to the same or like elements. Moreover, the drawings are only exemplary and not illustrated based on actual scale. The embodiments only provide illustrative description for a part of the scope and implementation of the disclosure.

In some embodiments, the sequence of processes or the order for assembling elements may be the same as or different from the embodiments described herein. In addition, not all the processes or elements described herein are necessary to implement the disclosure.

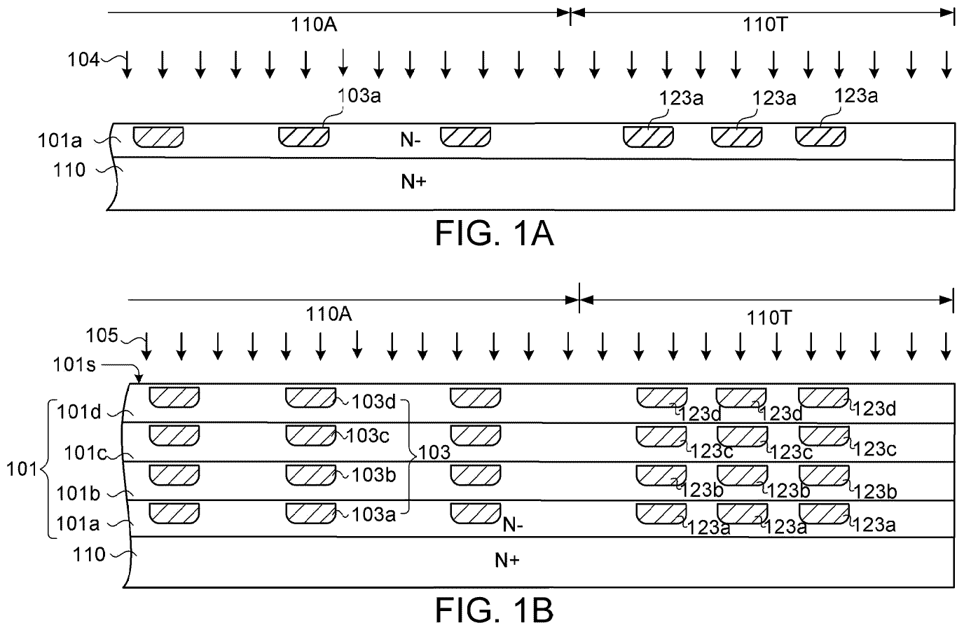

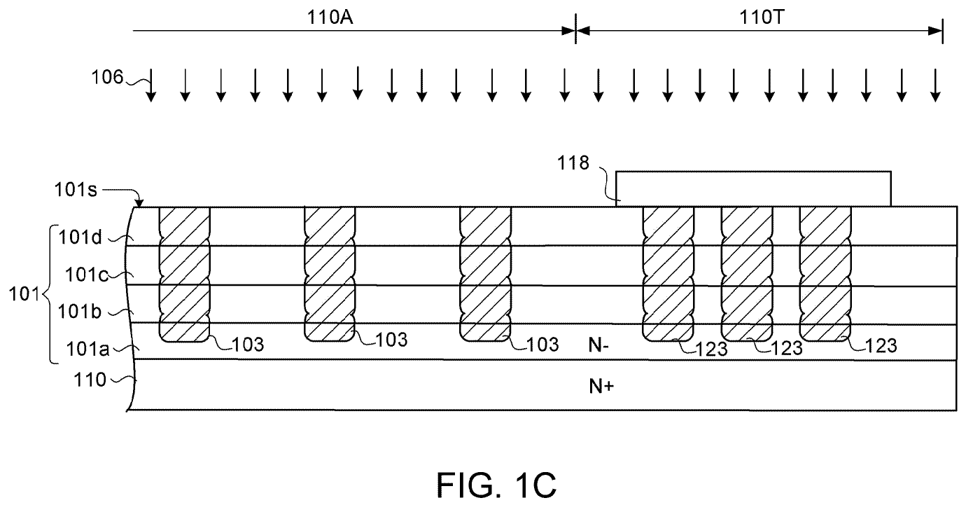

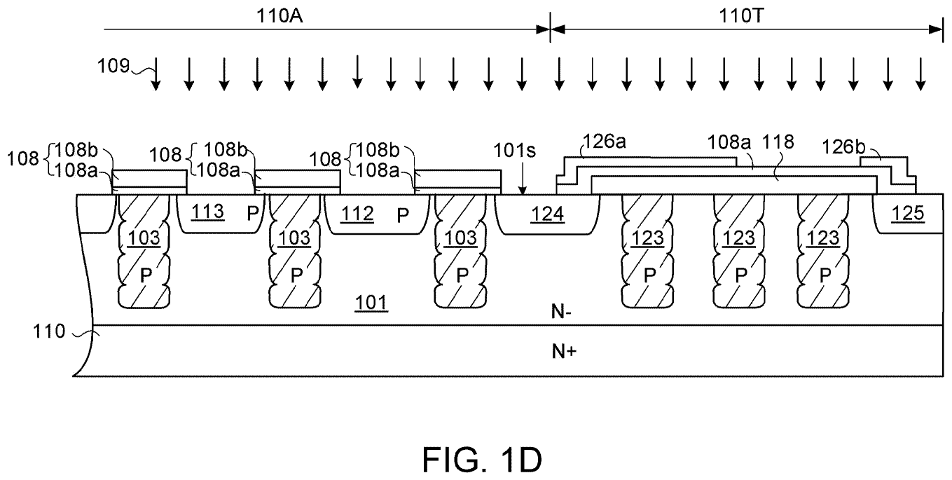

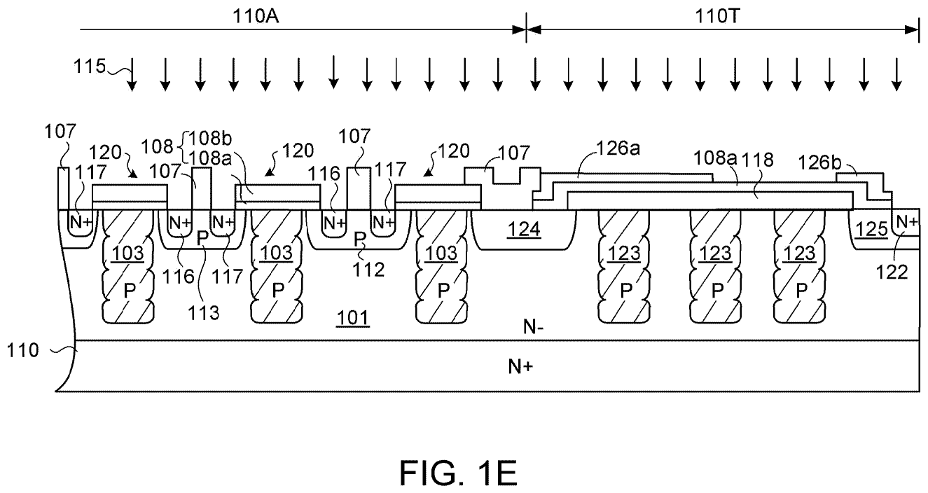

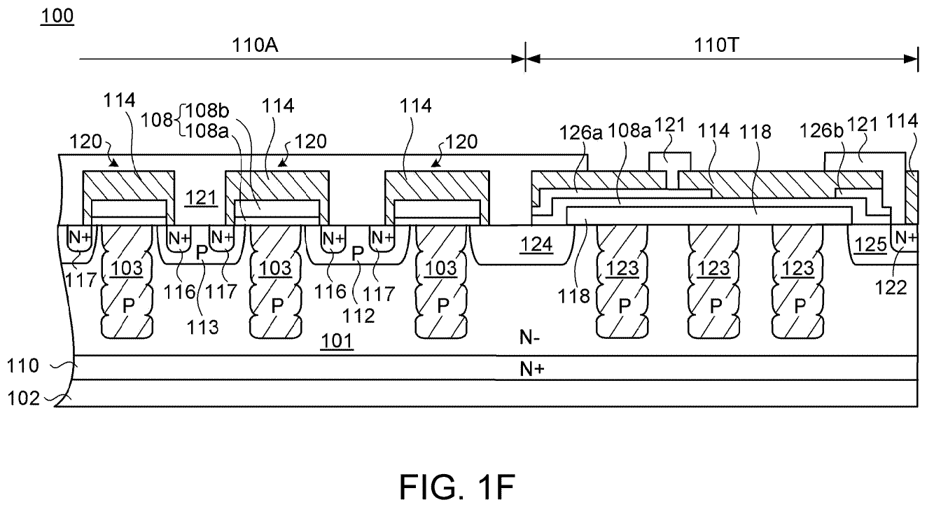

Referring to FIG. 1A to FIG. 1F, FIG. 1A to FIG. 1F are schematic cross-sectional views of structures in a series of fabrication processes of fabricating a power semiconductor device 100 according to an embodiment of the disclosure. The fabrication method of the power semiconductor device 100 includes the following. First, an epitaxial layer 101 having a first conductive type is provided. At least one floating doped region 103 having a second conductive type is formed in the epitaxial layer 101, as shown in FIG. 1B.

Some embodiments of the disclosure may include an epitaxial deposition process, in which the semiconductor epitaxial layer 101 having an n-type dopant (e.g. pentavalent atoms such as arsenic, phosphorus, antimony) grows on a semiconductor substrate 110 having an n-type dopant, and the floating doped region 103 is formed. In some embodiments of the disclosure, the floating doped region 103 and the epitaxial layer 101 may be simultaneously formed on the semiconductor substrate 110 through a multi-layered epitaxial layer fabrication process.

In the embodiment, the semiconductor substrate 110 may be a silicon carbide. The semiconductor substrate 110 may be divided into at least one active region 110A and a terminal region 110T located at an outside of the active region 110A. However, the disclosure is not limited thereto. For example, in some embodiments, the terminal region 110T may be omitted.

The multi-layered epitaxial layer fabrication process of fabricating the epitaxial layer 101 and the floating doped region 103 includes the following. First, a first epitaxial layer 101a having an n-conductive type is formed above the semiconductor substrate 110. Then, by masking a portion of the first epitaxial layer 101a with a patterned photoresist (not shown) and performing an ion implantation process 104, a dopant (e.g. trivalent atoms such as aluminum, boron, gallium) having a p-conductive type is implanted into the first epitaxial layer 101a. Hence, multiple first ion implantation regions 103a having the p-conductive type are formed in the first epitaxial layer 101a above the active region 110A. At the same time, multiple ion implantation regions 123a having the p-conductive type are formed in the first epitaxial layer 101a above the terminal region 110T (as shown in FIG. 1A).

Next, a second epitaxial layer 101b having the n-conductive type is formed above the first epitaxial layer 101a. Then, by masking a portion of the second epitaxial layer 101b with a patterned photoresist (not shown) and performing an ion implantation process 105, a dopant having the p-conductive type is implanted into the second epitaxial layer 101b. Hence, second ion implantation regions 103b having the p-conductive type is formed in the second epitaxial layer 101b above the active region 110A so that the second ion implantation regions 103b and the first ion implantation regions 103a are at least partially overlapped but separated from each other. Furthermore, ion implantation regions 123b having the p-conductive type are formed in the second epitaxial layer 101b above the terminal region 110T so that the ion implantation regions 123b and the ion implantation regions 123a are respectively at least partially overlapped but separated from each other.

Next, by repeating the processes of forming the second ion implantation regions 103b and the ion implantation regions 123b, multiple epitaxial layers stacked to one another are formed on the polycrystalline silicon substrate 110 and multiple ion implantation regions mutually overlapped are formed in the epitaxial layers. As a result, the fabrication of the floating doped region 103 and the epitaxial layer 101 is completed. In some embodiments of the disclosure, a material of the epitaxial layer 101 may be the same as or different from a material of the semiconductor substrate 110. In the embodiment, a doping concentration (N−) of the n-type dopant in the epitaxial layer 101 is substantially lower than a doping concentration (N+) of the n-type dopant in the semiconductor substrate 110 (e.g. silicon carbide).

In the embodiment, the epitaxial layer 101 may include, but not limited to, the first epitaxial layer 101a, the second epitaxial layer 101b, a third epitaxial layer 101c, and a fourth epitaxial layer 101d that are mutually overlapped. The first epitaxial layer 101a, the second epitaxial layer 101b, the third epitaxial layer 101c, and the fourth epitaxial layer 101d located above the active region 110A respectively include the first ion implantation region 103a, the second ion implantation region 103b, a third ion implantation region 103c, and a fourth ion implantation region 103d having the same or different sizes and doping concentrations and separated from each other. The first epitaxial layer 101a, the second epitaxial layer 101b, the third epitaxial layer 101c, and the fourth epitaxial layer 101d located above the terminal region 110T respectively include multiple sets of ion implantation regions 123a, 123b, 123c, and 123d having the same or different sizes and doping concentrations and separated from each other (as shown in FIG. 1B).

In some embodiments of the disclosure, after each epitaxial layer is formed, it is not required to form an ion implantation region in the epitaxial layer. In the process of fabricating the epitaxial layer 101 and the floating doped region 103, the ion implantation process may be omitted at least once if needed. In addition, there is no limit to a doping concentration and/or a dopant implantation depth formed and an area of an ion implantation region implanted in each ion implantation process. In other words, a depth, a width, an area range, and a doping concentration of an ion implantation region formed in each ion implantation process may be the same or different, and two ion implantation regions that are vertically adjacent may contact or be separated from each other.

Next, a dielectric material layer is formed on the epitaxial layer 101. By performing a patterning process 106, a dielectric layer 118 covering the epitaxial layer 101 of the terminal region 110T is formed. The dielectric material layer may be a silicon oxide layer and may be formed by performing a thermal oxidation process. When the thermal oxidation process is performed, a dopant with the p-conductive type in the first ion implantation region 103a, the second ion implantation region 103b, the third ion implantation region 103c, and the fourth ion implantation region 103d may be driven in at the same time to cause enlarge diffusion of the dopant to expand the areas of these regions to be further connected to each other. As a result, the multiple floating doped regions 103 may be formed in the epitaxial layer 101 above the active region 110A. Furthermore, a dopant with the p-conductive type in the ion implantation regions 123a, 123b, 123c, and 123d may be driven in to cause enlarge diffusion of the dopant to expand the areas of these regions to be further connected to each other. As a result, multiple floating doped regions 123 may be formed in the epitaxial layer 101 above the terminal region 110T (as shown in FIG. 1C).

Next, referring to FIG. 1D, multiple gate structures 108 are formed on the epitaxial layer 101 above the active region 110A. The gate structures 108 and the floating doped regions 103 are at least partially overlapped. In the embodiment, forming the gate structure 108 includes the following. After the dielectric layer 118 (e.g. the silicon oxide layer) is formed on a surface 101s of the epitaxial layer 101, another dielectric layer and a conductive layer (not shown) are sequentially formed above the active region 110A. The dielectric layer and the conductive layer above the active region 110A are patterned by performing a photolithography process, thereby forming the gate structure 108 including a dielectric layer 108a and a gate electrode 108b on the surface 101s of the epitaxial layer 101 above the active region 110A. The gate structure 108 is aligned with the floating doped region 103. In some embodiments of the disclosure, the gate structure 108 may only be partially overlapped with the floating doped region 103.

In addition, when the multiple gate structures 108 are formed, the dielectric layer 108a and at least one interconnect 126a or conductive feature 126b may be formed in the terminal region 110T and a transition region (e.g. a region at the end of the terminal region 110T and the end of the active region 110A). The interconnect 126a or the conductive feature 126b is electrically isolated from the epitaxial layer 101 through the dielectric layer 118 (e.g. the silicon oxide layer) and the dielectric layer 108a.

Then, by using the gate structures 108 as a mask, an ion implantation process 109 is performed to form a first well region 112 and a second well region 113 separated from each other and having the p-conductive type in the epitaxial layer 101 in the active region 110A. The first well region 112 and the second well region 113 extend from the surface 101s of the epitaxial layer 101 into the epitaxial layer 101 so that the floating doped region 103 is located between the first well region 112 and the second well region 113 and is separated from the first well region 112 and the second well region 113. In the ion implantation process 109, a doped well region 124 having the p-conductive type is further formed in the epitaxial layer 101 in the transition region between the terminal region 110T and the active region 110A. A doped well region 125 having the p-conductive type and surrounding the power semiconductor device 100 is formed at the periphery of the terminal region 110T (as shown in FIG. 1D).

After the first well region 112, the second well region 113, the doped well region 124, and the doped well region 125 are formed, a portion of the terminal region 110T and a portion of the first well region 112 and the second well region 113 are covered with a patterned photoresist layer 107. Then, by using the photoresist layer 107 and the gate structures 108 as a mask, another ion implantation process 115 is performed to form a first doped region 116 and a second doped region 117 having the n-conductive type in the active region 110A. The first doped region 116 and the second doped region 117 respectively extend downwards from the surface 101s of the epitaxial layer 101 into the first well region 112 and the second well region 113, and are adjacent to the gate structure 108. In the ion implantation process 115, a doped region 122 having the n-conductive type is further formed in the terminal region 110T. The doped region 122 having the n-conductive type extends downwards from the surface 101s of the epitaxial layer 101 into the doped well region 125 (as shown in FIG. 1E). In some embodiments of the disclosure, a doping concentration (N+) of the n-type dopant in the first doped region 116 and the second doped region 117 is substantially higher than a doping concentration (N−) of the n-type dopant in the epitaxial layer 101.

In the embodiment, the first well region 112, the second well region 113, the first doped region 116, and the second doped region 117 adjacent to each of the gate structures 108, as well as the floating doped region 103, a portion of the epitaxial layer 101, and a portion of the semiconductor substrate 110 located below the gate structure 108 may form a vertically structured power metal-oxide-semiconductor transistor unit 120 (cell). The first doped region 116 and the second doped region 117 adjacent to the gate structure 108 may serve as the source of the power metal-oxide-semiconductor transistor unit 120. The portion of the epitaxial layer 101 below the gate structure 108 may serve as a channel layer of the double-diffused power metal-oxide-semiconductor transistor unit 120. The portion of the semiconductor substrate 110 and a drain metal layer 102 (which has not be formed for the time being, see FIG. 1F) located below the gate structures 108 may serve as the drain of the double-diffused power metal-oxide-semiconductor transistor unit 120. In some embodiments, multiple double-diffused power metal-oxide-semiconductor transistor units 120 may form a double-diffused power metal-oxide-semiconductor transistor array.

The patterned photoresist layer 107 is removed, and then a subsequent process is performed. A patterned dielectric layer 114 is formed above the epitaxial layer 101 to cover the terminal region 110T and the gate structure 108. A patterned metal contact layer 121 is formed on the dielectric layer 114. A portion of the metal contact layer 121 contacts the source (the first doped region 116 and the second doped region 117) of the double-diffused power metal-oxide-semiconductor transistor unit 12 to connect in parallel the multiple power metal-oxide-semiconductor transistor units 120. Next, a portion of the semiconductor substrate 110 is removed by performing a thinning process and, for example, by performing a deposition process or a surface bonding process, the drain metal layer 102 is formed at the other side of the thinned semiconductor substrate 110 opposite to the epitaxial layer 101. As a result, the fabrication of the power semiconductor device 100 is completed (as shown in FIG. 1F).

In addition, in some embodiments of the disclosure, a portion of the patterned metal contact layer 121 covers the terminal region 110T and respectively electrically contacts the interconnect 126a and the doped region 122, thereby increasing a critical voltage of the power semiconductor device 100. In an embodiment of the disclosure, the portion of the patterned metal contact layer 121 electrically contacting the interconnect 126a may be connected to the gate electrode 108b. In addition, the part of the patterned metal contact layer 121 electrically contacting the doped region 122 may be floating, and the doped well region 125 and the doped region 122 with the n-conductive type form a channel stop at the periphery of the terminal region 110T. The channel stop prevents an electrical field from expanding outwards when the power semiconductor device 100 is reversely cut off, thereby helping regulate a breakdown voltage of the power semiconductor device 100.

The floating doped region 103 embedded in each of the double-diffused power metal-oxide-semiconductor transistor units 120 is able to effectively spread the electrical field since the floating doped region 103 has an conductive type opposite to the channel (the epitaxial layer 101) and extends downwards to approach the drain (the drain metal layer 102) of the power metal-oxide-semiconductor transistor unit 120. When the parasitic diode of the super junction metal-oxide-semiconductor transistor unit 120 is switched from a forward operation to a reverse operation, the flow of the current caused by other passive devices on the circuit from the source to the drain of the super junction metal-oxide-semiconductor transistor unit 120 is reduced. When the diode current of the super junction metal-oxide-semiconductor transistor unit 120 is reduced to zero, carriers initially parasitic in the parasitic diode of the super junction metal-oxide-semiconductor transistor unit 120 form a reverse current due to a voltage polarity switch. The floating doped region 103 helps reduce carriers in the parasitic diode and the reverse current in the power metal-oxide-semiconductor transistor unit 120, thereby effectively reducing the reverse current and power consumption, helping switch the operations of the power metal-oxide-semiconductor transistor unit 120, and effectively reducing the reverse recovery time. As a result, it is favorable for the power semiconductor device 100 to be operated at a high frequency. At the same time, when the device is switched to be turned off, the floating doped region 103 is able to further expand a depletion region in the epitaxial layer 101, thereby increasing the critical voltage of the power metal-oxide-semiconductor transistor unit 120.

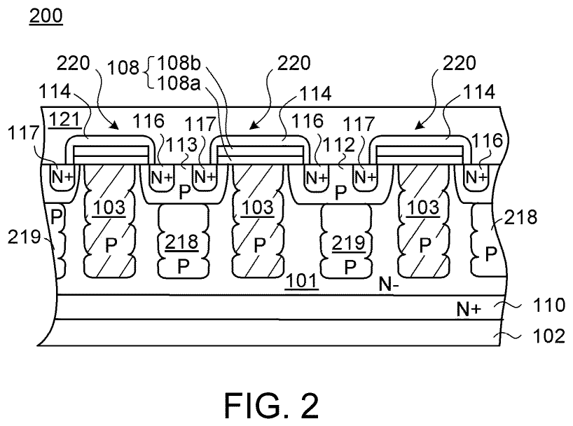

Referring to FIG. 2, FIG. 2 is a schematic cross-sectional view of a structure of a power semiconductor device 200 according to another embodiment of the disclosure. The structure of the power semiconductor device 200 is similar to the structure of the power semiconductor device 100 shown in FIG. 1F. The major difference lies in the following. An active region of the power semiconductor device 200 further includes a third doped region 218 and a fourth doped region 219 located in the epitaxial layer 101 and having the p-conductive type. The third doped region 218 and the fourth doped region 219 are respectively connected to the first well region 112 and the second well region 113 so that the floating doped region 103 is located between the third doped region 218 and the fourth doped region 219. Since the structure of a terminal region of the power semiconductor device 200 is substantially similar to the structure shown in FIG. 1F and the fabrication method is described in detail above, relevant details will not be repeated in the following.

In the embodiment, the third doped region 218 and the fourth doped region 219 are simultaneously formed by adopting the same multi-layered epitaxial layer fabrication process (as shown in FIG. 1A to FIG. 1B) of the floating doped region 103 and the epitaxial layer 101. Except for the difference in positions from the first ion implantation region 103a, the second ion implantation region 103b, the third ion implantation region 103c, and the fourth ion implantation region 103d forming the floating doped region 103, the ion implantation regions forming the third doped region 218 and the fourth doped region 219 share the same processes and parameters of fabrication as those in the process of fabricating the floating doped region 103. Therefore, relevant details will not be repeated in the following.

In the embodiment, a doping concentrations (P) of a p-type dopant in the third doped region 218 and the fourth doped region 219 is substantially equal to a doping concentration (P) of a p-type dopant in the floating doped region 103. However, the position, the size, and the concentration of the p-type dopant of each of the ion implantation regions forming the third doped region 218 and the fourth doped region 219 are not limited thereto. In a process of forming the third doped region 218 and the fourth doped region 219, the parameter of each of the ion implantation processes in the multi-layered epitaxial layer fabrication process may be adjusted according to an actual fabrication process condition and a device demand of the power semiconductor device 200, thereby modifying the position, the size, and the concentration of the p-type dopant of each of the ion implantation regions in the third doped region 218 and the fourth doped region 219.

As shown in FIG. 2, each of the gate structures 108, the first well region 112, the second well region 113, the first doped region 116, and the second doped region 117 adjacent to the gate structures 108, and the floating doped region 103, a portion of the epitaxial layer 101, and a portion of the third doped region 218 and the fourth doped region 219 located below the gate structure 108 may form a vertically structured super junction metal-oxide-semiconductor transistor unit 220.

The third doped region 218, the fourth doped region 219, and the floating doped region 103 embedded in each of the super junction metal-oxide-semiconductor transistor units 220 is able to effectively spread the electrical field since the third doped region 218, the fourth doped region 219, and the floating doped region 103 have an conductive type opposite to the channel (the epitaxial layer 101) and extend downwards to approach the drain (the drain metal layer 102) of the super junction metal-oxide-semiconductor transistor unit 220. In a process in which the super junction metal-oxide-semiconductor transistor unit 220 is switched from the forward operation to the reverse operation, since a reverse current caused by other passive devices on the circuit may flow from the source of the super junction metal-oxide-semiconductor transistor unit 220 to the drain, the super junction metal-oxide-semiconductor transistor unit 220 is thus turned off. Then, when the super junction metal-oxide-semiconductor transistor unit 220 is switched from the off state to the reverse operation, carriers initially parasitic in a diode of the super junction metal-oxide-semiconductor transistor unit 220 flows out and forms a reverse current due to a voltage polarity switch. The floating doped region 103 helps reduce carriers in the parasitic diode and the reverse current in the super junction metal-oxide-semiconductor transistor unit 220, thereby effectively reducing the reverse current and power consumption, helping switch the operations of the super junction metal-oxide-semiconductor transistor unit 220, and effectively reducing the reverse recovery time. As a result, it is favorable for the power semiconductor device 200 to be operated at a high frequency. At the same time, when the device is switched to be turned off, the floating doped region 103 is able to further expand a depletion region in the epitaxial layer 101, thereby increasing the critical voltage of the super junction metal-oxide-semiconductor transistor unit 220.

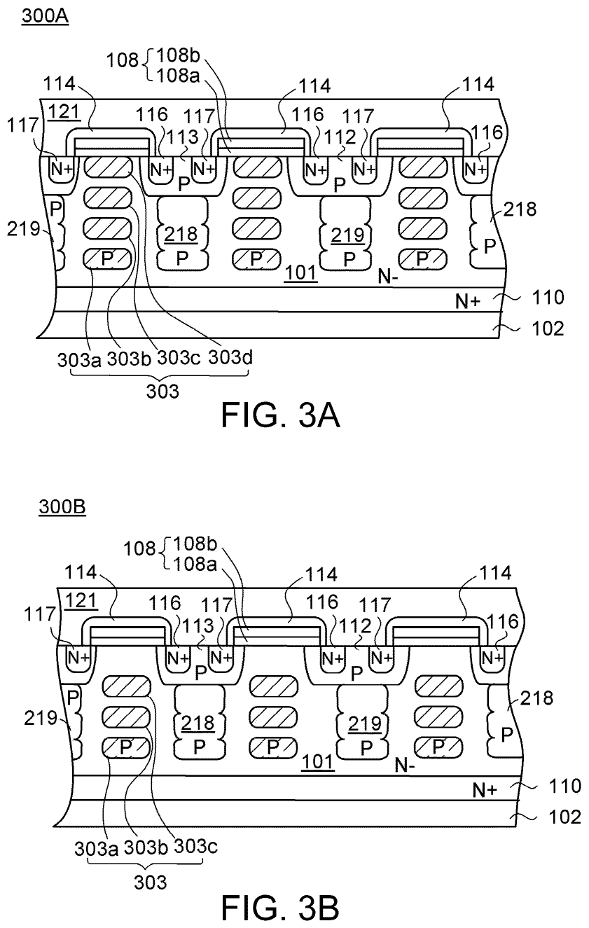

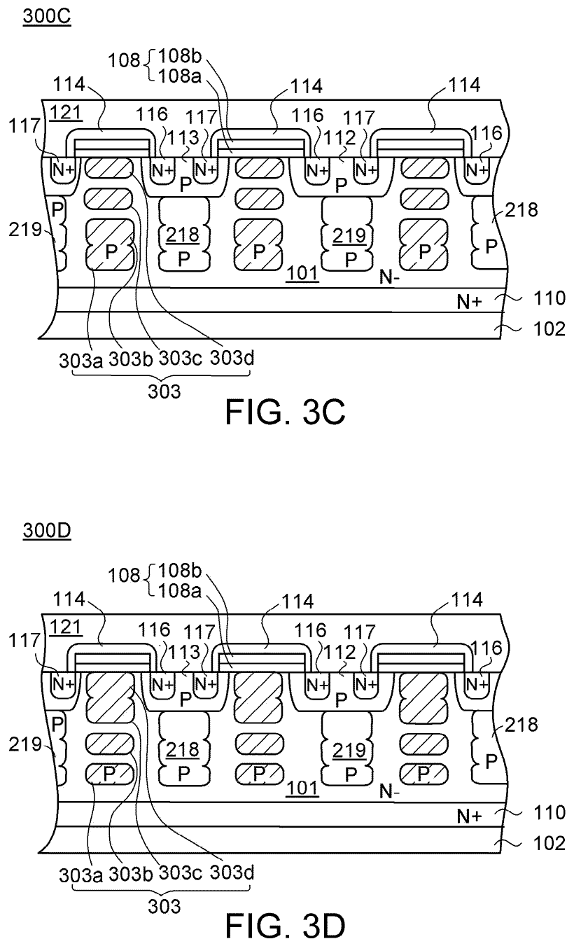

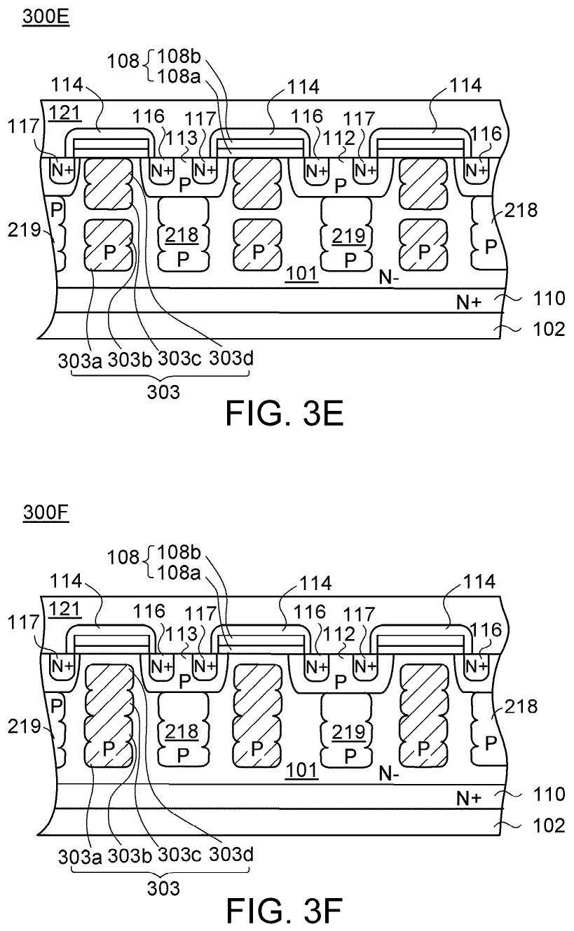

Referring to FIG. 3A to FIG. 3F, FIG. 3A to FIG. 3F are schematic cross-sectional views respectively illustrating structures of power semiconductor devices 300A, 300B, 300C, 300D, 300E, and 300F having floating doped regions 303 with different structures according to some embodiments of the disclosure. The structures of the power semiconductor devices 300A, 300B, 300C, 300D, 300E, and 300F are similar to the power semiconductor device 200 shown in FIG. 2. The major difference is that a first ion implantation region 303a, a second ion implantation region 303b, a third ion implantation region 303c, and a fourth ion implantation region 303d forming the floating doped region 303 of the power semiconductor devices 300A, 300B, 300C, 300D, 300E, and 300F are in different arrangements. Since the structures of the terminal regions of the power semiconductor devices 300A, 300B, 300C, 300D, 300E, and 300F are substantially similar to the structure shown in FIG. 1F and the fabrication method is described in detail above, relevant details will not be repeated in the following.

As shown in FIG. 3A, in the power semiconductor device 300A, the first ion implantation region 303a, the second ion implantation region 303b, the third ion implantation region 303c, and the fourth ion implantation region 303d forming the floating doped region 303 are separated from each other, and the fourth ion implantation region 303d directly contacts the dielectric layer 108a of the gate structure 108. In FIG. 3B, the fourth ion implantation region 303d is omitted in the power semiconductor device 300B, and the rest first ion implantation region 303a, second ion implantation region 303b, and third ion implantation region 303c are separated from each other.

In FIG. 3C, the first ion implantation region 303a and the second ion implantation region 303b on the lower side are connected to each other, and the connected region on the lower side, the third ion implantation region 303c above the connected region, and the fourth ion implantation region 303d above the connected region are separated from each other. The fourth ion implantation region 303d directly contacts the dielectric layer 108a. In FIG. 3D, the third ion implantation region 303c and the fourth ion implantation region 303d on the upper side are connected to each other, and the connected region on the upper side, the first ion implantation region 303a below the connected region, and the second ion implantation region 303b below the connected region are separated from each other. The fourth ion implantation region 303d directly contacts the dielectric layer 108a.

In FIG. 3E, the first ion implantation region 303a and the second ion implantation region 303b on the lower side are connected to each other, and the third ion implantation region 303c and the fourth ion implantation region 303d on the upper side are connected to each other. The connected regions on the upper side and the lower side are separated from each other. The fourth ion implantation region 303d directly contacts the dielectric layer 108a. In FIG. 3F, the first ion implantation region 303a, the second ion implantation region 303b, the third ion implantation region 303c, and the fourth ion implantation region 303d are connected to each other, and neither of the first ion implantation region 303a, the second ion implantation region 303b, the third ion implantation region 303c, and the fourth ion implantation region 303d directly contacts the dielectric layer 108a.

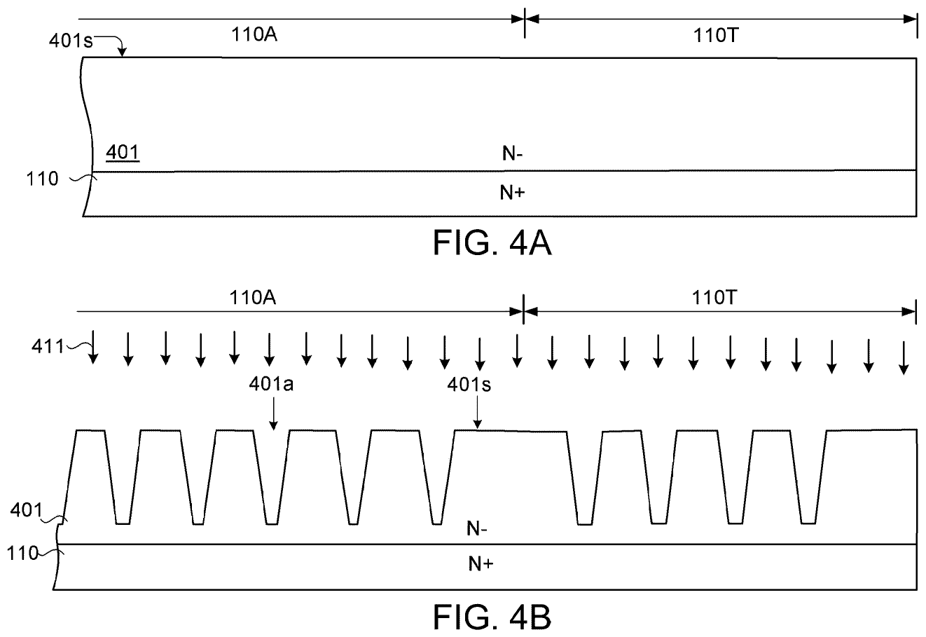

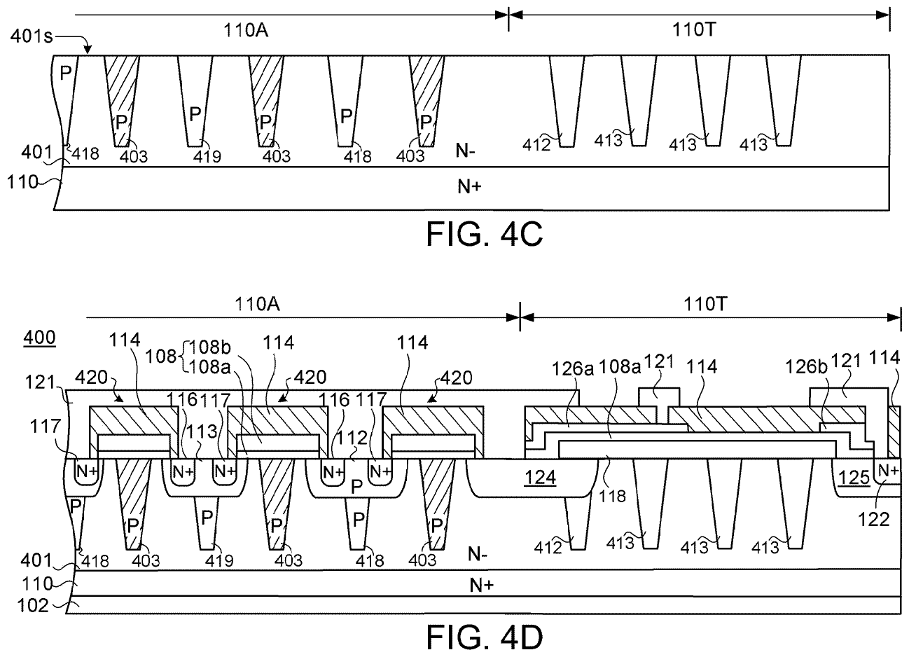

Referring to FIG. 4A to FIG. 4D, FIG. 4A to FIG. 4D are schematic cross-sectional views of structures of some of the fabrication processes of fabricating a power semiconductor device 400 according to still another embodiment of the disclosure. A fabrication method of the power semiconductor device 400 is similar to the fabrication method of the power semiconductor device 200. The major difference is how a floating doped region 403, a third doped region 418, and a fourth doped region 419 are fabricated.

In the embodiment, the floating doped region 403, the third doped region 418, and the fourth doped region 419 are fabricated in an epitaxial layer 401 by performing a deep trench backfilling process. The deep trench backfilling process may include the following. First, the epitaxial layer 401 grows on the semiconductor substrate 110 having the n-type dopant (e.g. pentavalent atoms such as arsenic, phosphorus, antimony) by performing an epitaxial deposition process such as a physical vapor deposition process or a chemical vapor deposition process (as shown in FIG. 4A). A material of the semiconductor substrate 110 and the epitaxial layer 401 may include silicon carbide. The doping concentration (N−) of the n-type dopant in the epitaxial layer 401 is substantially lower than the doping concentration (N+) of the n-type dopant in the polycrystalline silicon substrate 110. The semiconductor substrate 110 may be divided into the at least one active region 110A and the terminal region 110T located at the outside of the active region.

Next, by performing a dry etching process 411, multiple deep trenches 401a are formed in the epitaxial layer 401. The deep trenches 401a extend from a surface 401s of the epitaxial layer 401 into the epitaxial layer 401 (as shown in FIG. 4B). Then, by performing a deposition process (e.g. a physical vapor deposition process or a chemical vapor deposition process), a polycrystalline silicon material having a p-type dopant is formed on the surface 401s of the epitaxial layer 401 and fills the deep trenches 401a. Next, by performing a planarization process, the polycrystalline silicon material with the p-type dopant except for those on the surface 401s of the epitaxial layer 401 is removed, thereby forming p-type deposition structures as shown in FIG. 4C. The p-type deposition structures located in the deep trenches 401a of the active region 110A may respectively serve as the floating doped region 403, the third doped region 418, and the fourth doped region 419 of the power semiconductor device 400. The p-type deposition structures located in the deep trenches 401a of the active region 110A may include at least one p-type deposition structure 412 located in the transition region between the terminal region 110T and the active region 110A and other p-type deposition structures 413 located in the terminal region 110T. The p-type deposition structures 413 are floating. In addition, the number of the p-type deposition structure 412 and the number of the p-type deposition structure 413 are not particularly limited and help increase the critical voltage of the power semiconductor device 400.

Next, the gate structure 108 is formed on the epitaxial layer 401 in the active region 110A. The first well region 112 and the second well region 113 separated from each other and having the p-conductive type are formed in the epitaxial layer 401 in the active region 110A. The doped well region 124 having the p-conductive type is formed in the epitaxial layer 401 in the transition region between the terminal region 110T and the active region 110A and is overlapped with a portion of the p-deposition structure 412. The doped well region 125 having the p-conductive type and surrounding the power semiconductor device 400 is formed at the periphery of the terminal region 110T. The first doped region 116, the second doped region 117, and the doped region 122 having the n-conductive type are respectively formed in the first well region 112, the second well region 113, and the doped well region 125.

Each of the gate structures 108, the first well region 112, the second well region 113, the first doped region 116, and the second doped region 117 adjacent to the gate structure 108, and the floating doped region 403, a portion of the epitaxial layer 401, a portion of the semiconductor substrate 110, a portion of the drain metal layer 102 (which has not been formed for the time being, see FIG. 4D), the third doped region 418 and the fourth doped region 419 located below the gate structure 108 may form a super junction metal-oxide-semiconductor transistor unit 420. Next, a subsequent process is performed. A portion of the semiconductor substrate 110 is removed by performing a thinning process and the drain metal layer 102 is formed at the other side of the thinned semiconductor substrate 110 opposite to the epitaxial layer 401. As a result, the fabrication of the power semiconductor device 400 having a super junction metal-oxide-semiconductor transistor array is completed (as shown in FIG. 4D).

The third doped region 418, the fourth doped region 419, and the floating doped region 403 embedded in each of the super junction metal-oxide-semiconductor transistor units 420 is able to effectively spread the electrical field since the third doped region 418, the fourth doped region 419, and the floating doped region 403 have an conductive type opposite to the channel (the epitaxial layer 401) and extend downwards to approach the drain (the drain metal layer 102) of the super junction metal-oxide-semiconductor transistor unit 420. When the parasitic diode of the super junction metal-oxide-semiconductor transistor unit 420 is switched from a forward operation to a reverse operation, the flow of the current caused by other passive devices of the circuit from the source to the drain of the super junction metal-oxide-semiconductor transistor unit 420 is reduced. When the diode current of the super junction metal-oxide-semiconductor transistor unit 420 is reduced to zero, carriers initially parasitic in the parasitic diode of the super junction metal-oxide-semiconductor transistor unit 420 form a reverse current due to a voltage polarity switch. The floating doped region 403 helps reduce carriers in the parasitic diode and the reverse current in the super junction metal-oxide-semiconductor transistor unit 420, thereby effectively reducing the reverse current and power consumption, helping switch the operations of the super junction metal-oxide-semiconductor transistor unit 420, and effectively reducing the reverse recovery time. As a result, it is favorable for the power semiconductor device 400 to be operated at a high frequency. At the same time, when the device is switched to be turned off, the floating doped region 403 is able to further expand a depletion region in the epitaxial layer 401, thereby increasing the critical voltage of the super junction metal-oxide-semiconductor transistor unit 420.

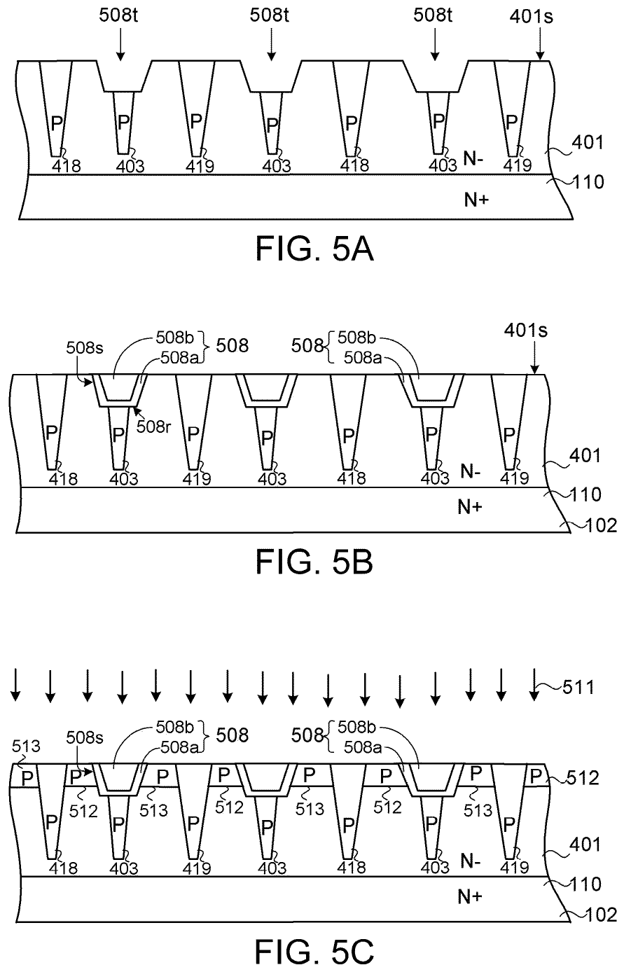

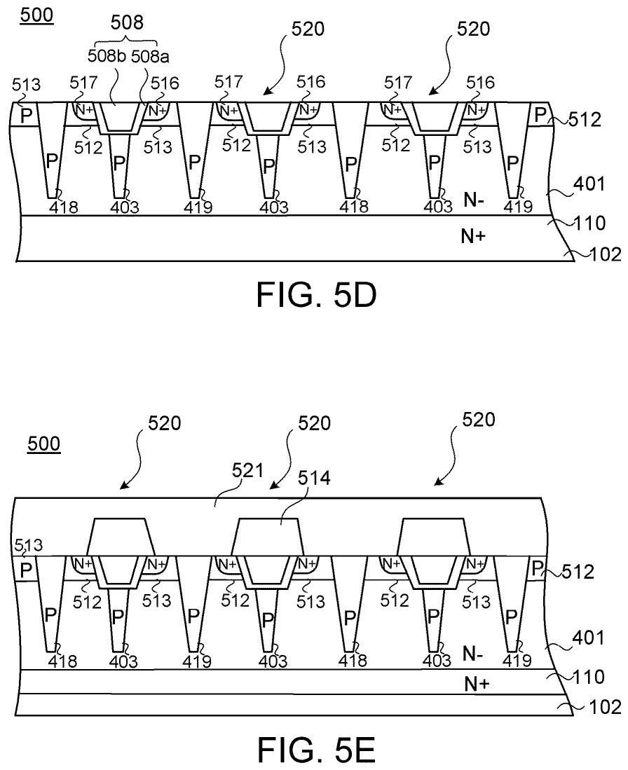

Referring to FIG. 5A to FIG. 5E, FIG. 5A to FIG. 5E are schematic cross-sectional views of structures of some of the fabrication processes of fabricating a power semiconductor device 500 according to yet another embodiment of the disclosure. A fabrication method of the power semiconductor device 500 is similar to the fabrication method of the power semiconductor device 400. The major difference lies in the fabrication of a gate structure 508. Since the structure of the terminal region of the power semiconductor device 500 is substantially similar to the structure shown in FIG. 4D and the fabrication method is described in detail above, relevant details will not be repeated in the following.

The process of fabricating the gate structure 508 includes the following. First, a trench 508t extending downwards from the surface 401s of the epitaxial layer 401 into the epitaxial layer 401 is formed in the epitaxial layer 401 as shown in FIG. 4C. The trench 508t is aligned with the floating doped region 403 and at least partially overlapped with the floating doped region 403 (as shown in FIG. 5A). Next, a dielectric layer 508a is formed and covers a sidewall 508s and a bottom surface 508r of the trench 508t. A gate electrode 508b is formed in the trench and is electrically isolated from the epitaxial layer 401 through the dielectric layer 508a (as shown in FIG. 5B).

Next, by performing an ion implantation process 511 in the epitaxial layer 401, a first well region 512 and a second well region 513 separated from each other and having the p-conductive type (as shown in FIG. 5C) are formed. A first doped region 516 and a second doped region 517 having the n-conductive type are respectively formed in the first well region 512 and the second well region 513 (as shown in FIG. 5D).

In the embodiment, each of the gate structures 508, the first well region 512, the second well region 513, the first doped region 516, and the second doped region 517 adjacent to the gate structure 508, and the floating doped region 403, a portion of the epitaxial layer 401, a portion of the semiconductor substrate 110, and a portion of the drain metal layer 102 (which has not been formed for the time being, see FIG. 5E) located below the gate structure 508 may form a power metal-oxide-semiconductor transistor unit 520 having a trench gate structure. The first doped region 516 and the second doped region 517 adjacent to the gate structure 508 may serve as the source of the trench gate power metal-oxide-semiconductor transistor unit 520. The portion of the epitaxial layer 401 located below the gate structure 508 may serve as a channel layer of the trench gate power metal-oxide-semiconductor transistor unit 520. The portion of the semiconductor substrate 110 and the portion of the drain metal layer 102 located below the gate structure 508 (as shown in FIG. 5E) may serve as the drain of the trench gate power metal-oxide-semiconductor transistor unit 520. In some embodiments, multiple trench gate power metal-oxide-semiconductor transistor units 520 may form a trench gate power metal-oxide-semiconductor transistor array.

Next, a subsequent process is performed. An interlayer dielectric layer 514 is formed on the surface 401s of the epitaxial layer 401, and a metal contact layer 521 is formed in and on the interlayer dielectric layer 514 to contact the source (the first doped region 516 and the second doped region 517) of the trench gate power metal-oxide-semiconductor transistor unit 520 to connect in parallel the multiple trench gate power metal-oxide-semiconductor transistor units 520. Next, by performing a thinning process, a portion of the semiconductor substrate 110 is removed and, for example, by performing a deposition process or a surface bonding process, the drain metal layer 102 is formed at the other side of the thinned semiconductor substrate 110 opposite to the epitaxial layer 401. As a result, the fabrication of the power semiconductor device 500 is completed (as shown in FIG. 5E).

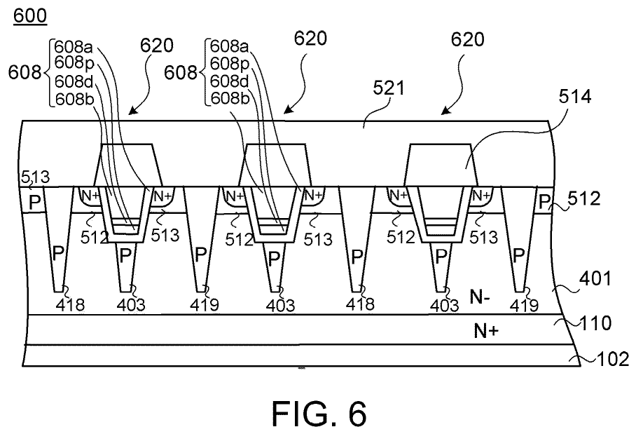

Referring to FIG. 6, FIG. 6 is a schematic cross-sectional view of a structure of a power semiconductor device 600 according to yet another embodiment of the disclosure. The structure of the power semiconductor device 600 is similar to the structure of the power semiconductor device 500. The major difference is that a gate structure 608 further includes a split gate. Since the structure of the terminal region of the power semiconductor device 600 is substantially similar to the structure shown in FIG. 4D and the fabrication method is described in detail above, relevant details will not be repeated in the following.

The process of fabricating the gate structure 608 includes the following. A dielectric layer 608a is formed in the trench 508t as shown in FIG. 5A and covers the sidewall 508s and the bottom 508r of the trench 508t. A split gate electrode 608p is formed at the bottom 508r of the trench 508t and a dielectric isolation layer 608d is electrically isolated from the epitaxial layer 401 through the dielectric layer 608a. The dielectric isolation layer 608d is formed above the split gate electrode 608p. A gate electrode 608b is formed above the dielectric isolation layer 608d. The gate electrode 608b is electrically isolated from the split gate electrode 608p through the dielectric isolation layer 608d, and, at the same time, the gate electrode 608b is electrically isolated from the epitaxial layer 401 through the dielectric layer 608a.

Next, by performing the ion implantation process 511 (as shown in FIG. 5C) in the epitaxial layer 401, the first well region 512 and the second well region 513 separated from each other and having the p-conductive type are formed. The first doped region 516 and the second doped region 517 having the n-conductive type are respectively formed in the first well region 512 and the second well region 513 (as shown in FIG. 5D). In some embodiments, multiple trench gate power metal-oxide-semiconductor transistor units 620 may form a trench gate power metal-oxide-semiconductor transistor array. Next, a subsequent process is performed. The interlayer dielectric layer 514 is formed on the surface 401s of the epitaxial layer 401, and the metal contact layer 521 is formed in and on the interlayer dielectric layer 514. The metal contact layer 521 contacts the source (the first doped region 516 and the second doped region 517) of the trench gate power metal-oxide-semiconductor transistor unit 620 to connect in parallel the multiple trench gate power metal-oxide-semiconductor transistor units 620. The fabrication of the power semiconductor device 600 as shown in FIG. 6 is completed.

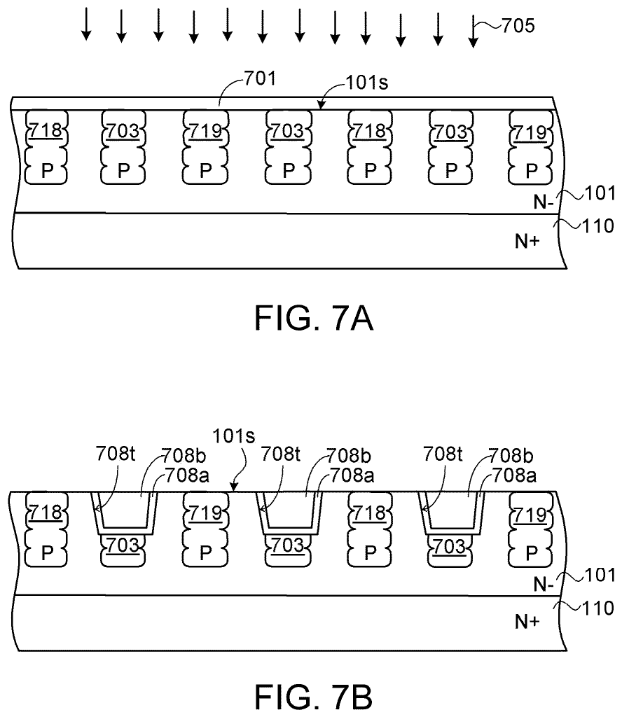

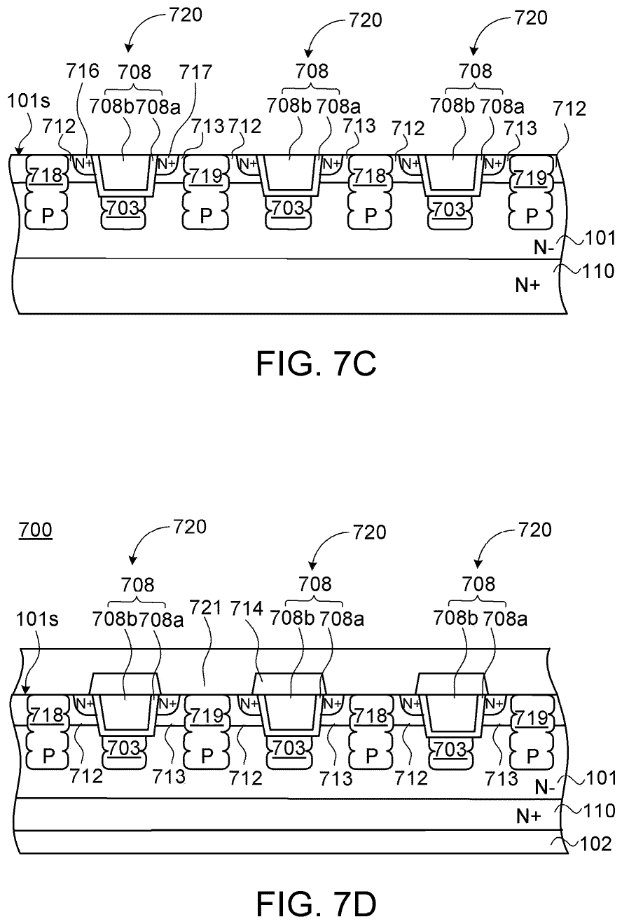

Referring to FIG. 7A to FIG. 7D, FIG. 7A to FIG. 7D are schematic cross-sectional views of structures of a power semiconductor device 700 according to yet another embodiment of the disclosure. The structure of the power semiconductor device 700 is similar to the structure of the power semiconductor device 500. The major difference is that a fabrication process of a floating doped region 703, a third doped region 718, and a fourth doped region 719 and the structures of the floating doped region 703, the third doped region 718, and the fourth doped region 719 are different. Since the structure of the terminal region of the power semiconductor device 700 is substantially similar to the structure shown in FIG. 1F and the fabrication process is described in detail above, relevant details will not be repeated in the following.

The process of fabricating the floating doped region 703, the third doped region 718, and the fourth doped region 719 includes the following. First, the processes in FIG. 1A to 1B are adopted. The epitaxial layer 101 including, but not limited to, the first epitaxial layer 101a, the second epitaxial layer 101b, the third epitaxial layer 101c, and the fourth epitaxial layer 101d that are overlapped with each other is formed above the semiconductor substrate 110. Each of the first epitaxial layer 101a, the second epitaxial layer 101b, the third epitaxial layer 101c, and the fourth epitaxial layer 101d respectively includes the first ion implantation region 103a, the second ion implantation region 103b, the third ion implantation region 103c, and the fourth ion implantation region 103d having the same or different sizes and doping concentrations and separated from each other (as shown in FIG. 1B).

Next, a thermal oxidation process 705 is adopted. A silicon oxide layer 701 is formed on the surface 101s of the epitaxial layer 101 to drive in the dopant with the p-conductive type in the first ion implantation region 103a, the second ion implantation region 103b, the third ion implantation region 103c, and the fourth ion implantation region 103d to expand downwards and to be connected to each other. Hence, multiple floating doped regions 703, third doped regions 718, and fourth doped regions 719 are respectively formed in the epitaxial layer 101 (as shown in FIG. 7A).

Then, a trench 708t is formed in the epitaxial layer 101 and extends downwards from the surface 101s of the epitaxial layer 101 into the epitaxial layer 101. The trench 708t is aligned with the floating doped region 703 and at least partially overlapped with the floating doped region 703. Next, a gate dielectric layer 708a is formed to cover a sidewall and a bottom surface of the trench 708t. A gate electrode 708b is formed in the trench 708t and is electrically isolated from the epitaxial layer 101 through the gate dielectric layer 708a. Accordingly, a gate structure 708 is formed in each of the trenches 708t (as shown in FIG. 7B).

By performing an ion implantation process (not shown) in the epitaxial layer 101, a first well region 712 and a second well region 713 separated from each other and having the p-conductive type are formed. In addition, a first doped region 716 and a second doped region 717 having the n-conductive type are respectively formed in the first well region 712 and the second well region 713 (as shown in FIG. 7C).

In the embodiment, each of the gate structures 708, the first well region 712, the second well region 713, the first doped region 716, and the second doped region 717 that are adjacent to the gate structure 708, and the floating doped region 703, a portion of the epitaxial layer 101, a portion of the semiconductor substrate 110, a portion of the drain metal layer 102 (which has not been formed for the time being, see FIG. 7D) located below the gate structure 708 may form a power metal-oxide-semiconductor transistor unit 720 having a trench gate structure. The first doped region 716 and the second doped region 717 adjacent to the gate structure 708 may serve as a source of the trench gate power metal-oxide-semiconductor transistor unit 720. The portion of the epitaxial layer 101 below the gate structure 708 may serve as a channel layer of the trench gate power metal-oxide-semiconductor transistor unit 720. The portion of the semiconductor substrate 110 and the portion of the drain metal layer 102 below the gate structure 708 may serve as a drain of the trench gate power metal-oxide-semiconductor transistor unit 720. In some embodiments, multiple trench gate power metal-oxide-semiconductor transistor units 720 may form a trench gate power metal-oxide-semiconductor transistor array.

Next, a subsequent process is performed. An interlayer dielectric layer 714 is formed on the surface 101s of the epitaxial layer 101, and a metal contact layer 721 is formed in and above the interlayer dielectric layer 714. The metal contact layer 721 contacts the source (the first doped region 716 and the second doped region 717) of the trench gate power metal-oxide-semiconductor transistor unit 720 to connect in parallel the multiple trench gate power metal-oxide-semiconductor transistor units 720. Next, by performing a thinning process, a portion of the semiconductor substrate 110 is removed. Next, for example, by performing a deposition process or a surface bonding process, the drain metal layer 102 at the other side of the thinned semiconductor substrate 110 opposite to the epitaxial layer 101 is formed. As a result, the fabrication of the power semiconductor device 700 is completed (as shown in FIG. 7D).

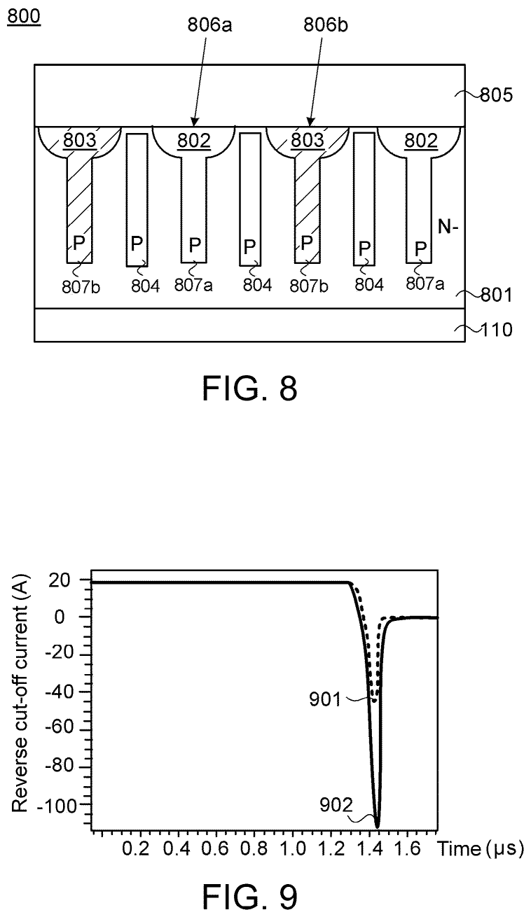

Referring to FIG. 8, FIG. 8 is a schematic cross-sectional view of a structure of a power semiconductor device 800 according to yet another embodiment of the disclosure. The power semiconductor device 800 includes the substrate 110, an epitaxial layer 801 having the n-conductive type, a first well region 802, a second well region 803, a column-shaped doped region 807a, a column-shaped doped region 807b, a floating doped region 804, and a metal electrode layer 805. The epitaxial layer 801 is formed on the substrate 110. The first well region 802 and the second well region 803 have the p-conductive type and respectively extend from a surface 801s of the epitaxial layer 801 into the epitaxial layer 801. The first well region 802 and the second well region 803 are separated from each other. The column-shaped doped regions 807a and 807b are located in the epitaxial layer 801 and below the first well region 802 and the second well region 803. The column-shaped doped regions 807a and 807b are respectively connected to the first well region 802 and the second well region 803. The floating doped region 804 has the p-conductive type and is located in the epitaxial layer 801 and between the first well region 802 and the second well region 803 and separated from the first well region 802 and the second well region 803. The metal electrode layer 805 is located on the epitaxial layer 801 and forms a metal-semiconductor junction 806a and a metal-semiconductor junction 806b respectively with the first well region 802 and the second well region 803.

Referring to FIG. 9, FIG. 9 is a curve chart of a relation between a reverse recovery current (Irr) and a reverse recovery time (trr) obtained when the power semiconductor device 400 provided in FIG. 4D and a conventional super junction metal oxide-semiconductor transistor unit without the floating doped region 403 underwent a reverse recovery test. Under the condition of the same rated operation voltage, the reverse recovery current and the reverse recovery time of the power semiconductor device 400 and the conventional super junction metal oxide-semiconductor transistor unit were measured.

In FIG. 9, a curve 901 represents a relation curve between the reverse recovery current and the reverse recovery time of the power semiconductor device 400, and a curve 902 represents a relation curve between the reverse recovery current and the reverse recovery time of the conventional super junction metal oxide-semiconductor transistor unit.

FIG. 9 shows that the reverse recovery current and the reverse recovery time of the power semiconductor device 400 are less than the reverse recovery current and the reverse recovery time of the conventional super junction metal oxide-semiconductor transistor unit. Accordingly, by providing the floating doped region 403, the reverse recovery current and the reverse recovery time of the power semiconductor device 400 are significantly reduced.

According to the embodiments above, in the power semiconductor device and the fabrication method thereof according to the disclosure, at least one transistor unit or metal-semiconductor junction diode unit having a vertical channel and an NPN parasitic bipolar junction is formed in the epitaxial layer having the first conductive type. Furthermore, the floating doped region having the second conductive type is disposed in the epitaxial layer to change a vertical electrical field distribution in the transistor/diode unit. When the transistor unit/diode is operated reversely, the injection of electrons from the drain into a parasitic PN junction between the drain and the source is facilitated so that the electrons are recombined with minority carriers accumulated in the PN junction. The reverse recovery time required to turn off a field effect transistor unit can be reduced without changing the rated operation voltage, which is favorable for the power semiconductor to be operated at a high frequency.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A power semiconductor device, comprising:
an epitaxial layer having a first conductive type;
a first well region having a second conductive type and extending from a surface of the epitaxial layer into the epitaxial layer, wherein the first well region includes a first doped region and a second doped region, both having the first conductive type, and the first doped region and the second doped region are spaced apart from each other;
a second well region having the second conductive type, extending from the surface of the epitaxial layer into the epitaxial layer, and separated from the first well region, wherein the second well region includes another first doped region and another second doped region, and the another first doped region and the another second doped region are spaced apart from each other;
a floating doped region having the second conductive type, located in the epitaxial layer and between the first well region and the second well region, and separated from the first well region and the second well region, wherein at least a portion of the floating doped region is positioned above a bottom surface wall of the first well region; and
a gate structure located on the epitaxial layer, adjacent to the first doped region and the second doped region, and at least partially overlapped with the floating doped region.

2. The power semiconductor device according to claim 1, wherein the floating doped region is longitudinally divided into at least two ion implantation regions, wherein a first ion implantation region is positioned above the bottom wall of the first well region, and at least a portion of a second ion implantation region is positioned above the bottom wall.

3. The power semiconductor device according to claim 2, wherein the at least two ion implantation regions are connected to each other.

4. The power semiconductor device according to claim 2, wherein the at least two ion implantation regions are separated from each other.

5. The power semiconductor device according to claim 1, wherein the floating doped region connects to a top surface of the epitaxial layer.

6. The power semiconductor device according to claim 1, wherein the floating doped region is spaced apart from a top surface of the epitaxial layer.

7. The power semiconductor device according to claim 1, the floating doped region has a wavy sidewall surface.

8. The power semiconductor device according to claim 1, wherein the floating doped region is longitudinally divided into a plurality of separated ion implantation regions, and wherein a first ion implantation region is connected to a top surface of the epitaxial layer.

9. The power semiconductor device according to claim 1, wherein the floating doped region is longitudinally divided into a plurality of separated ion implantation regions, and wherein a first ion implantation region is spaced apart from a top surface of the epitaxial layer.

10. The power semiconductor device according to claim 1, wherein the floating doped region is longitudinally divided into a plurality of separated ion implantation regions, and wherein a first ion implantation region is spaced apart from a top surface of the epitaxial layer.

11. The power semiconductor device according to claim 1, wherein the floating doped region is longitudinally divided into a plurality of ion implantation regions, and wherein at least two adjacent ion implantation regions are connected to each other, with their connecting sidewalls having a wavy profile.

12. The power semiconductor device according to claim 11, wherein there are four ion implantation regions, wherein a third ion implantation region is separated from both a second ion implantation region and a fourth ion implantation region, and wherein a first ion implantation region is connected to the second ion implantation region.

13. The power semiconductor device according to claim 11, wherein there are four ion implantation regions, wherein a second ion implantation region is separated from both a first ion implantation region and a third ion implantation region, and wherein the third ion implantation region is connected to the fourth ion implantation region.

14. The power semiconductor device according to claim 11, wherein there are four ion implantation regions, wherein a second ion implantation region is separated from a third ion implantation region, wherein a first ion implantation region is connected to the second ion implantation region, and wherein the third ion implantation region is connected to a fourth ion implantation region.

15. The power semiconductor device according to claim 1, wherein the floating doped region is longitudinally divided into a plurality of separated ion implantation regions that are connected to one another, and has a wavy sidewall, and wherein a first ion implantation region is spaced apart from a top surface of the epitaxial layer.

16. The power semiconductor device according to claim 1, further comprising:
a third doped region having the second conductive type, located in the epitaxial layer, and connected to the first well region; and
a fourth doped region having the second conductive type, located in the epitaxial layer, and connected to the second well region so that the floating doped region is located between the third doped region and the fourth doped region.

17. The power semiconductor device according to claim 1, wherein the gate structure further comprises:
a gate dielectric layer located on the surface of the epitaxial layer and adjacent to the first doped region and the second doped region; and
a gate electrode located on the gate dielectric layer and electrically isolated from the epitaxial layer through the gate dielectric layer.

18. The power semiconductor device according to claim 1, wherein the gate structure further comprises:
a gate dielectric layer located in a trench and adjacent to the first doped region and the second doped region, wherein the trench extends from the surface of the epitaxial layer into the epitaxial layer; and
a gate electrode located in the trench and electrically isolated from the epitaxial layer through the gate dielectric layer.

19. The power semiconductor device according to claim 18, wherein the gate structure further comprises:
a split gate located at a bottom of the trench and electrically isolated from the epitaxial layer through the gate dielectric layer; and
a dielectric isolation layer located in the trench and electrically isolating the split gate and the gate electrode.
